(19) United States
(12) Patent Application Publication
(10) Pub. No.: US 2025/0079315 A1
(43) Pub. Date: Mar. 6, 2025

(54) SEMICONDUCTOR STRUCTURE AND METHOD FOR FORMING THE SAME

(71) Applicant: Winbond Electronics Corp., Taichung City (TW)

(72) Inventors: Jian-Ting CHEN, Taichung City (TW); Yao-Ting TSAI, Kaohsiung City (TW); Bo-Lun WU, Taichung City (TW); Sih-Han CHEN, Changhua County (TW)

(73) Assignee: Winbond Electronics Corp., Taichung City (TW)

(21) Appl. No.: 18/677,434

(22) Filed: May 29, 2024

(30) Foreign Application Priority Data
Aug. 28, 2023 (TW) 112132260

(51) Int. Cl. H01L 23/532; H01L 21/768; H01L 23/528

(52) U.S. Cl. CPC H01L 23/5329; H01L 21/76814; H01L 21/76828; H01L 21/76831; H01L 21/76868; H01L 23/5283

(57) ABSTRACT

The method for forming the semiconductor structure includes the following steps. A substrate that is divided into a cell region and a peripheral region is provided. A bottom dielectric layer is formed on the substrate. A first stacked structure and a second stacked structure are formed on the bottom dielectric layer. The first stacked structure is disposed in the cell region and the second stacked structure is disposed in the peripheral region. The first stacked structure is patterned to form first conductive stacks. A first cleaning process is performed. A first repair dielectric layer is formed on the first conductive stacks, the second stacked structure, and the bottom dielectric layer. The second stacked structure is patterned to form second conductive stacks. A second cleaning process is performed. A second repair dielectric layer is formed on the first conductive stacks, the second conductive stacks, and the bottom dielectric layer.

### CROSS REFERENCE TO RELATED APPLICATIONS

This application claims priority of Taiwan Patent Application No. 112132260, filed on Aug. 28, 2023, the entirety of which is incorporated by reference herein.

### BACKGROUND OF THE INVENTION

### Field of the Invention

The present invention relates to a semiconductor structure and a method for forming the same, and, in particular, to a method for forming a semiconductor structure that includes two repair dielectric layers and the semiconductor structure formed thereby.

### Description of the Related Art

With the miniaturization of semiconductor structures (e.g., dynamic random access memory, DRAM) and the streamlining of the manufacturing process, damage often occurs to the bottom dielectric layer and sidewalls of the conductive stacks (e.g., gate stacks in the cell region) during cleaning processes in the process of manufacturing the semiconductor structures. Therefore, it is necessary to use repair dielectric layers to repair said damage.

In traditional processes, overly thick repair dielectric layers are often formed to prevent electrical shorts that such damage can cause. This results in difficulties in forming conductive components (such as a source and drain embedded in the substrate) within the substrate in the peripheral region, or it necessitates additional photolithography and etching processes to remove parts of the overly thick repair dielectric layer.

### BRIEF SUMMARY OF THE INVENTION

An embodiment of the present invention provides a semiconductor structure and a method for forming the same. The method for forming the semiconductor structure in the embodiments of the present invention effectively prevents electrical shorts caused by damage during the cleaning process and allows for the successful formation of conductive components within the substrate in the peripheral region without additional photolithography and etching processes.

Some embodiments of the present invention provide a method for forming a semiconductor structure, which includes the following steps. A substrate that is divided into a cell region and a peripheral region adjacent to the cell region is provided. A bottom dielectric layer is formed on the substrate. A first stacked structure and a second stacked structure are formed on the bottom dielectric layer. The first stacked structure is disposed in the cell region and the second stacked structure is disposed in the peripheral region. The first stacked structure is patterned to form first conductive stacks. A first cleaning process is performed. A first repair dielectric layer is formed on the first conductive stacks, the second stacked structure, and the bottom dielectric layer. The second stacked structure is patterned to form second conductive stacks. A second cleaning process is performed. A second repair dielectric layer is formed on the first conductive stacks, the second conductive stacks, and the bottom dielectric layer.

Some embodiments of the present invention provide a semiconductor structure. The semiconductor structure includes a substrate. The substrate has a cell region and a peripheral region that is adjacent to the cell region. The semiconductor structure also includes a bottom dielectric layer disposed on the substrate. The semiconductor structure further includes multiple first conductive stacks and multiple second conductive stacks. The first conductive stacks are disposed on the bottom dielectric layer and in the cell region, and the second conductive stacks are disposed on the bottom dielectric layer and in the peripheral region. Moreover, the semiconductor structure includes a repair dielectric layer disposed on the first conductive stacks and the second conductive stacks. The repair dielectric layer has a first thickness on sidewalls of each first conductive stack and a second thickness on sidewalls of each second conductive stack, and the first thickness is greater than the second thickness.

### BRIEF DESCRIPTION OF THE DRAWINGS

FIG. 1 to FIG. 5 are partial cross-sectional views illustrating various stages of forming a semiconductor structure according to some embodiments of the present invention.

### DETAILED DESCRIPTION OF THE INVENTION

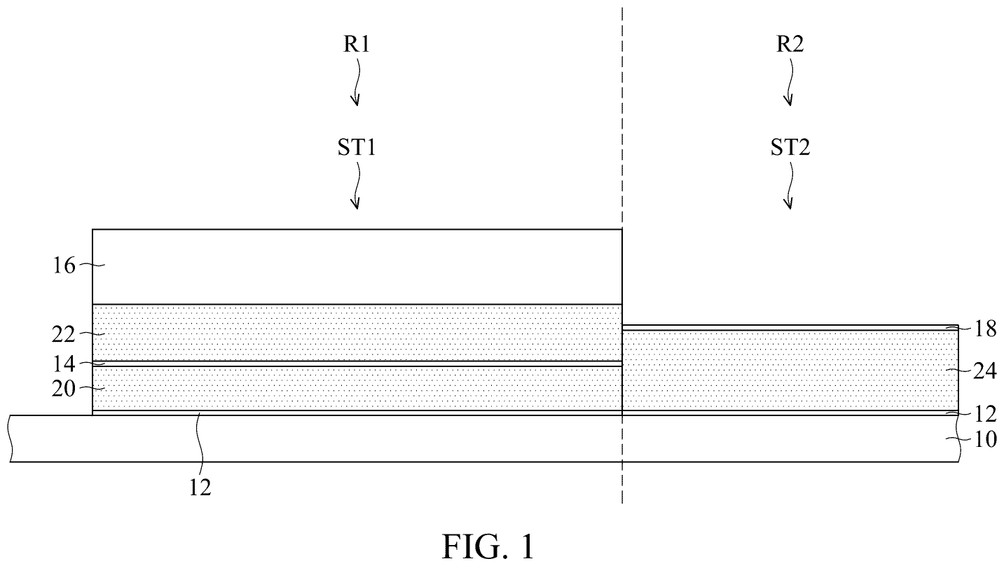

FIG. 1 to FIG. 5 are partial cross-sectional views illustrating various stages of forming a semiconductor structure 100 according to some embodiments of the present invention. It should be noted that some components of the semiconductor structure 100 have been omitted in FIG. 1 to FIG. 5 for the sake of brevity.

Referring to FIG. 1, a substrate 10 is provided. The substrate 10 is divided into a cell region R1 and a peripheral region R2, and the peripheral region R2 is adjacent to the cell region R1. For example, the peripheral region R2 of substrate 10 may surround the cell region R1, but the present disclosure is not limited thereto.

Referring to FIG. 1, a bottom dielectric layer 12 is formed on the substrate 10. For example, the bottom dielectric layer 12 may include insulating materials such as silicon oxide, silicon nitride, silicon oxynitride, similar substances, or a combination thereof, but the present disclosure is not limited thereto. The bottom dielectric layer 12 may be formed by a deposition process. The deposition process may include chemical vapor deposition, atomic layer deposition, molecular beam epitaxy, liquid-phase epitaxy, similar processes, or a combination thereof, but the present disclosure is not limited thereto.

Referring to FIG. 1, a first stack structure ST1 and a second stack structure ST2 are formed on the bottom dielectric layer 12. As shown in FIG. 1, the first stack structure ST1 is disposed in the cell region R1 of the substrate 10, while the second stack structure ST2 is disposed in the peripheral region R2 of the substrate 10. For example, the first stack structure ST1 may include semiconductor layers 20, 22, and an insulating layer 14, and the insulating layer 14 is disposed between the semiconductor layer 20 and the semiconductor layer 22. The second stack structure ST2 may include a semiconductor layer 24 and an insulating layer 18, and the insulating layer 18 is disposed on the semiconductor layer 24, but the present disclosure is not limited thereto. Moreover, the first stack structure ST1 may further include an insulating layer 16, and the insulating layer 16 is disposed on the semiconductor layer 22.

The semiconductor layers 20, 22, and 24 may include silicon or germanium, and the insulating layers 14, 16, and 18 may include silicon oxide, silicon nitride, silicon oxynitride, similar substances, or a combination thereof. The aforementioned material may be formed by a deposition process, but the present disclosure is not limited thereto. Examples of the deposition process are as mentioned above and will not be repeated here.

It should be noted that although FIG. 1 shows that the semiconductor layers 20 and 24 are directly formed on the bottom dielectric layer 12 (i.e., the semiconductor layers 20 and 24 are in direct contact with the bottom dielectric layer 12), the present disclosure is not limited thereto. There may be other components between the semiconductor layer 20 and the bottom dielectric layer 12 or between the semiconductor layer 24 and the bottom dielectric layer 12.

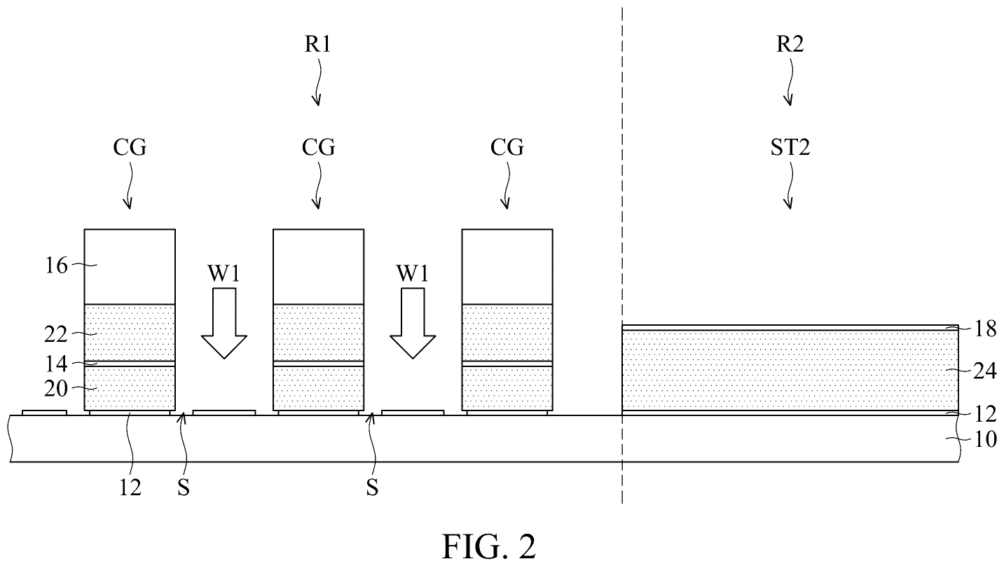

Referring to FIG. 2, the first stack structure ST1 is patterned to form multiple first conductive stacks CG. A patterning process may be performed to process the first stack structure ST1 according to the predetermined placement of the first conductive stacks CG. For example, a mask layer (not shown) is placed above (the insulating layer 16 of) the first stack structure ST1, and then the aforementioned mask layer is used as an etching mask for the etching process to etch grooves in the first stack structure ST1. The mask layer may include photoresist, such as positive photoresist or negative photoresist. Moreover, the mask layer may include a hard mask, and it may be formed from materials like silicon oxide (SiO₂), silicon nitride (SiN), silicon oxynitride (SiON), silicon carbide (SiC), silicon carbonitride (SiCN), similar materials, or a combination thereof, but the present disclosure is not limited thereto.

The mask layer may be a single-layer structure or a multi-layer structure. The formation of the mask layer may include a deposition process, a photolithography process, any other applicable process, or a combination thereof, but the present disclosure is not limited thereto.

Next, referring to FIG. 2, a first cleaning process W1 is performed. The first cleaning process W1 is used to remove excess components remaining from previous processes. In some embodiments, the first cleaning process W1 is a wet cleaning process that uses diluted hydrofluoric acid (HF) as a cleaning agent, but the present disclosure is not limited thereto.

As shown in FIG. 2, multiple gaps S are formed in the bottom dielectric layer 12 during the first cleaning process W1. the gaps S are close to the corners of the bottom of the first conductive stack CG, but the present disclosure is not limited thereto. For example, gaps S may also be formed in the semiconductor layer 20 or other layers of the first conductive stack CG during the first cleaning process W1 (not shown in FIG. 2).

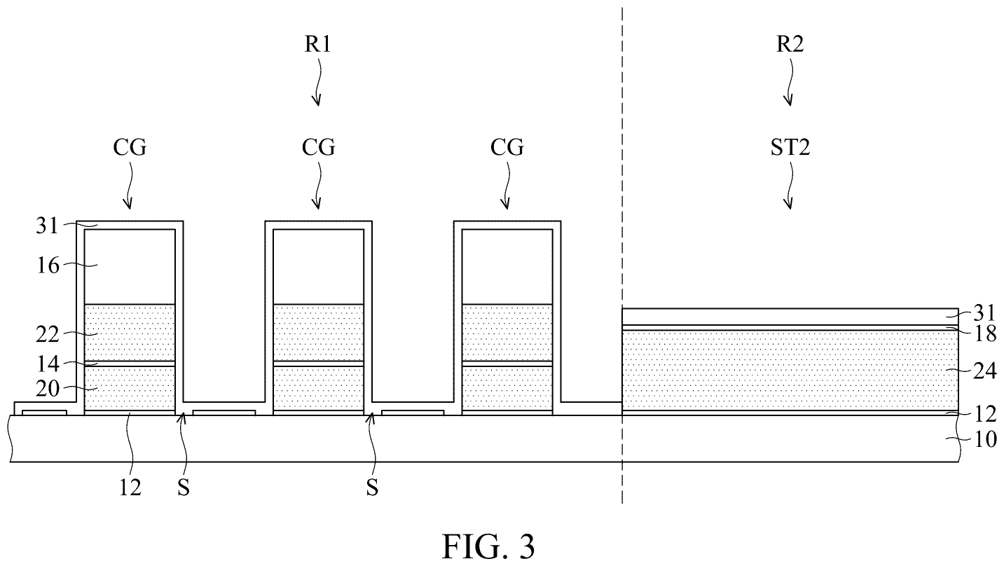

Then, referring to FIG. 3, a first repair dielectric layer 31 is formed on the first conductive stacks CG, the second stack structure ST2, and the bottom dielectric layer 12. The first repair dielectric layer 31 may include insulating materials, as previously described, and will not be repeated here. the first repair dielectric layer 31 fills the gaps S. The first repair dielectric layer 31 is used to prevent the gaps S from causing electrical shorts in subsequent processes.

In some embodiments, a thermal treatment process is performed to form the first repair dielectric layer 31. the thermal treatment process includes in-situ steam generation (ISSG) oxidation, rapid thermal oxidation (RTO), rapid thermal nitridation (RTN), but the present disclosure is not limited thereto.

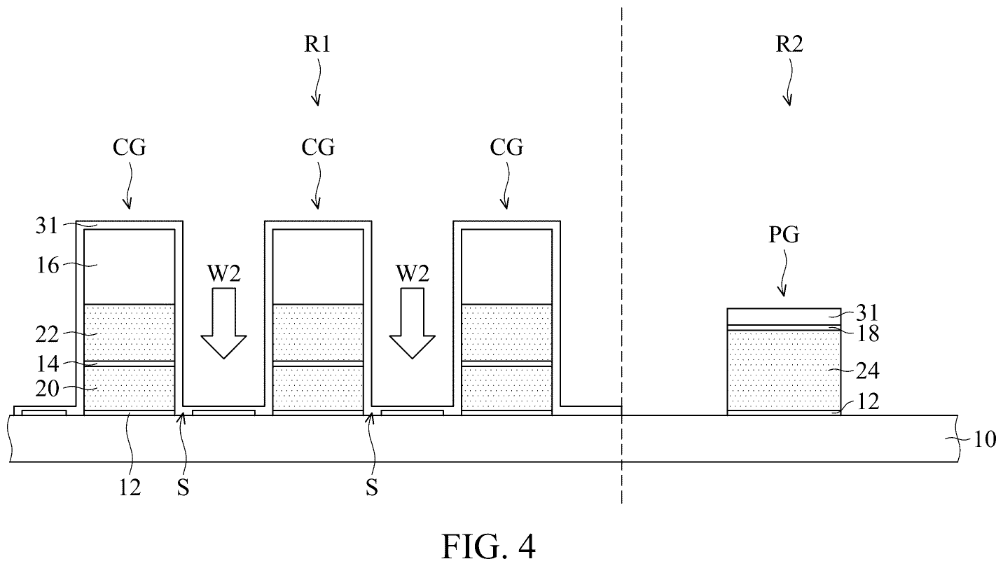

Next, referring to FIG. 4, the second stack structure ST2 is patterned to form multiple second conductive stacks PG (only one shown in FIG. 4). A patterning process may be performed to process the second stack structure ST2 according to the predetermined placement of the second conductive stacks PG. Examples of the patterning process are as mentioned above and will not be repeated here.

Next, referring to FIG. 4, a second cleaning process W2 is performed. The second cleaning process W2 is used to remove excess components remaining after previous processes. Similarly, the second cleaning process W2 is a wet cleaning process using diluted hydrofluoric acid (HF) as a cleaning agent, but the present disclosure is not limited thereto.

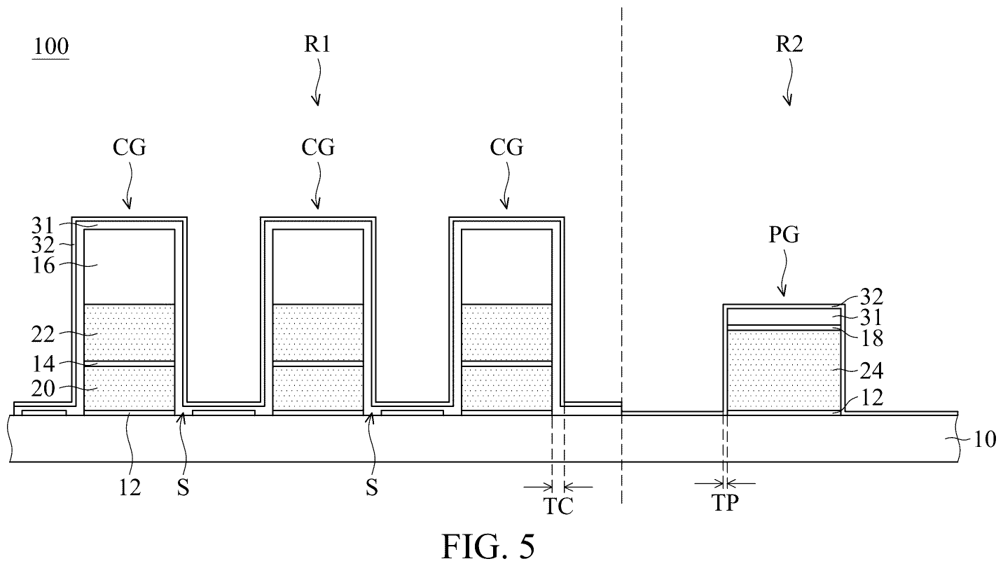

Then, referring to FIG. 5, a second repair dielectric layer 32 is formed on the first conductive stacks CG, the second conductive stacks PG, and the bottom dielectric layer 12 to form the semiconductor structure 100. The material of the second repair dielectric layer 32 may be the same as or similar to the material of the first repair dielectric layer 31. Moreover, a thermal treatment process is performed to form the second repair dielectric layer 32. Examples of the thermal treatment process are as mentioned above and will not be repeated here, but the present disclosure is not limited thereto.

Multiple gaps (not shown) may still be formed in the bottom dielectric layer 12, the first conductive stacks CG, or the second conductive stacks PG during the second cleaning process W2 as shown in FIG. 4. The second repair dielectric layer 32 may fill these gaps, preventing electrical shorts caused by the gaps. In other words, the first repair dielectric layer 31 and the second repair dielectric layer 32 may be considered as a repair dielectric layer for the bottom dielectric layer 12 and the first conductive stacks CG, while the second repair dielectric layer 32 may be considered as a repair dielectric layer for the second conductive stacks PG.

As shown in FIG. 5, the semiconductor structure 100 includes a substrate 10. The substrate has a cell region R1 and a peripheral region R2 that is adjacent to the cell region R1. The semiconductor structure 100 also includes a bottom dielectric layer 12 disposed on the substrate 10. The semiconductor structure 100 further includes multiple first conductive stacks CG and multiple second conductive stacks PG. The first conductive stacks CG are disposed on the bottom dielectric layer 12 and in the cell region R1, and the second conductive stacks PG are disposed on the bottom dielectric layer 12 and in the peripheral region R2.

The semiconductor structure 100 includes a repair dielectric layer disposed on the first conductive stacks CG and the second conductive stacks PG. The repair dielectric layer has a first thickness TC on sidewalls of each first conductive stack CG and a second thickness TP on sidewalls of each second conductive stack PG, and the first thickness TC is greater than the second thickness TP. Moreover, the repair dielectric layer includes oxides or nitrides.

The bottom dielectric layer 12 (or the first conductive stacks CG and/or the second conductive stacks PG) has multiple gaps S, and the repair dielectric layer fills the gaps S. Since the repair dielectric layer fills the gaps S, which may prevent electrical shorts caused by the gaps S.

Moreover, the thickness (e.g., the second thickness TP) of the repair dielectric layer (e.g., the second repair dielectric layer 32) in the peripheral region R2 (for example, on the sidewalls of each second conductive stack PG) is less than the thickness (e.g., the first thickness TC) in the cell region R1 (for example, on the sidewalls of each first conductive stack PG). Therefore, there is no need for additional photolithography and etching processes to remove a portion of the repair dielectric layer, and the conductive component in the substrate 10 may be successfully formed in the peripheral region R2.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

What is claimed is:

1. A method for forming a semiconductor structure, comprising:
providing a substrate, wherein the substrate is divided into a cell region and a peripheral region adjacent to the cell region;
forming a bottom dielectric layer on the substrate;
forming a first stacked structure and a second stacked structure on the bottom dielectric layer, wherein the first stacked structure is disposed in the cell region, and the second stacked structure is disposed in the peripheral region;
patterning the first stacked structure to form first conductive stacks;
performing a first cleaning process;
forming a first repair dielectric layer on the first conductive stacks, the second stacked structure, and the bottom dielectric layer;
patterning the second stacked structure to form second conductive stacks;
performing a second cleaning process; and
forming a second repair dielectric layer on the first conductive stacks, the second conductive stacks, and the bottom dielectric layer.

2. The method for forming the semiconductor structure as claimed in claim 1, wherein gaps are formed in the bottom dielectric layer during the first cleaning process, and the first repair dielectric layer fills the gaps.

3. The method for forming the semiconductor structure as claimed in claim 2, wherein the gaps are close to corners of a bottom of the first conductive stacks.

4. The method for forming the semiconductor structure as claimed in claim 1, wherein the first cleaning process or the second cleaning process is a wet cleaning process.

5. The method for forming the semiconductor structure as claimed in claim 4, wherein the wet cleaning process uses hydrofluoric acid as a cleaning agent.

6. The method for forming the semiconductor structure as claimed in claim 1, wherein a heat treatment process is performed to form the first repair dielectric layer or the second repair dielectric layer.

7. The method for forming the semiconductor structure as claimed in claim 6, wherein the heat treatment process comprises in-situ steam generation oxidation, rapid thermal oxidation, or rapid thermal nitridation.

8. The method for forming the semiconductor structure as claimed in claim 1, wherein the first stack structure comprises a first semiconductor layer, a second semiconductor layer, and a first insulating layer disposed between the first semiconductor layer and the second semiconductor layer.

9. The method for forming the semiconductor structure as claimed in claim 8, wherein the second stack structure comprises a third semiconductor layer and a second insulating layer disposed on the third semiconductor layer.

10. The method for forming the semiconductor structure as claimed in claim 9, wherein the first semiconductor layer and the third semiconductor layer are in direct contact with the bottom dielectric layer.

11. The method for forming the semiconductor structure as claimed in claim 1, wherein gaps are formed in the bottom dielectric layer, the first conductive stacks, or the second conductive stacks during the second cleaning process, and the second repair dielectric layer fills the gaps.

12. A semiconductor structure, comprising:
a substrate having a cell region and a peripheral region that is adjacent to the cell region;
a bottom dielectric layer disposed on the substrate;
first conductive stacks disposed on the bottom dielectric layer and in the cell region;
second conductive stacks disposed on the bottom dielectric layer and in the peripheral region;
a repair dielectric layer disposed on the first conductive stacks and the second conductive stacks.

13. The semiconductor structure as claimed in claim 12, wherein the repair dielectric layer has a first thickness on sidewalls of each of the first conductive stacks and a second thickness on sidewalls of each of the second conductive stacks, and the first thickness is greater than the second thickness.

14. The semiconductor structure as claimed in claim 12, wherein the bottom dielectric layer has gaps, and the repair dielectric layer fills the gaps.

15. The semiconductor structure as claimed in claim 12, wherein the repair dielectric layer comprises oxides or nitrides.

16. The semiconductor structure as claimed in claim 12, wherein each of the first conductive stacks comprises a first semiconductor layer, a second semiconductor layer, and a first insulating layer disposed between the first semiconductor layer and the second semiconductor layer.

17. The semiconductor structure as claimed in claim 16, wherein each of the second conductive stacks comprises a third semiconductor layer and a second insulating layer disposed on the third semiconductor layer.

18. The semiconductor structure as claimed in claim 17, wherein the first semiconductor layer and the third semiconductor layer are in direct contact with the bottom dielectric layer.
